(19) United States
(12) Patent Application Publication
(10) Pub. No.: US 2018/0368257 A1
(43) Pub. Date: Dec. 20, 2018

(54) SUBSTRATE FOR RECEIVING AN OPTOELECTRONIC COMPONENT, OPTOELECTRONIC ASSEMBLY, METHOD FOR PRODUCING A SUBSTRATE AND A METHOD FOR PRODUCING AN OPTOELECTRONIC ASSEMBLY

(71) Applicant: OSRAM GmbH, Munich (DE)

(72) Inventors: Bernd Barchmann, Regensburg (DE); Gertrud Kraeuter, Regensburg (DE); Matthias Loster, Regensburg (DE)

(21) Appl. No.: 16/011,689

(22) Filed: Jun. 19, 2018

(30) Foreign Application Priority Data
Jun. 19, 2017 (DE) 10 2017 210 200.4

(51) Int. Cl. H05K 1/05; C08K 9/04; H01L 33/00; H01L 33/64

(52) U.S. Cl. CPC H05K 1/056; H01L 33/64; H01L 33/005; C08K 9/04

(57) ABSTRACT

In various embodiments, a substrate for receiving an optoelectronic component is provided. The substrate includes a carrier body, and filler particles, which are embedded in the carrier body and which each have an electrically and thermally highly conductive core and an electrically insulating enveloping layer.

### CROSS-REFERENCE TO RELATED APPLICATION

This application claims priority to German Patent Application Serial No. 10 2017 210 200.4, which was filed Jun. 19, 2017, and is incorporated herein by reference in its entirety.

### TECHNICAL FIELD

Various embodiments relate generally to a substrate for receiving an optoelectronic component, an optoelectronic assembly, a method for producing a substrate and a method for producing an optoelectronic assembly.

### BACKGROUND

An optoelectronic assembly has at least one optoelectronic component and a substrate. The optoelectronic component is arranged on the substrate and electrically contacted on the substrate via at least one conductor track. By way of example, the optoelectronic component is an organic light emitting diode (OLED), a light emitting diode (LED), a light sensor or a solar cell. In recent years, such optoelectronic assemblies have found ever more applications, for example in the field of general illumination or in the automotive field. In particular, the long service life, the very good efficiency and the excellent color rendering helped establish corresponding optoelectronic components. By way of example, if it initially was retrofit light bulbs or retrofit halogen lamps that were available in the field of general illumination, luminaires with optoelectronic components have additionally become available in the meantime, which meet the needs of the specific illumination problem in an improved manner. In these, substrates equipped with LEDs are often installed directly in the luminaires. By way of example, a printed circuit board, a metal core circuit board or a ceramic substrate serves as a substrate.

The substrates should have a very good thermal conductivity so that heat arising during the operation of the optoelectronic component can be dissipated quickly and efficiently by way of the substrate. This contributes to the optoelectronic component being able to be operated in an operational range in which it is very efficient. Moreover, this can contribute to the optoelectronic component having a long service life. Further, this allows the optoelectronic component to be operated at a high power, in particular at a high operating current. This contributes to the optoelectronic assembly for producing light at a given luminous intensity only requiring few optoelectronic components. However, the substrates should be cost effective at the same time in order to be able to keep the costs for the optoelectronic assemblies low.

Although ceramic substrates and metal core circuit boards are distinguished by a substantially better thermal conductivity than CEM or FR4 printed circuit boards, they are significantly more expensive. Therefore, it is necessary to make compromises between good thermal conductivity and low costs on a regular basis. In order to keep costs low, attempts are made, for example, to minimize the number of required process steps when producing the optoelectronic assemblies. In order to obtain good thermal conductivity, attempts are made, for example, to reduce the number of thermal transitions by virtue of the luminaires and/or holders being embodied in such a way that they themselves act as substrates for the corresponding OLEDs or LEDs or light sensors or solar cells.

Various plastics lend themselves as materials for luminaires that can also serve as substrates. These can be brought into various forms by means of extrusion, injection molding or 3D shaping methods. Then, metallizations for producing circuit carriers can be embodied by means of hot stamping of structured metal films or by means of laser direct structuring (LDS) in the case of two-dimensional substrates. However, the conductor tracks produced in this way only contribute to a limited extent to the dissipation of the heat produced in the components on account of their low thickness and this integration of electrically and thermally conductive structures into freely formed plastics substrates requires a plurality of process steps and presumes the use of expensive materials and techniques, as a result of which the production costs are relatively high once again and an automization of the processes is complicated. By way of example, a thermally conductive plastic and, possibly, an insert piece must be used in addition to the expensive LDS method with wet chemistry in order to be able to sufficiently dissipate the heat emitted by mid- and high-power class LEDs.

Therefore, LED chips and packages in lamps and luminaires are often applied to separate, usually flat substrates as circuit carriers, said substrates having structures for conducting electric current and heat. In the case of low power classes with little development of heat, use can also be made of OLEDs or LEDs on flexible substrates.

Further, luminaires are known, in which thermally conductive plastics are used, which wholly or partly replace the materials of the substrates that were used up until now. These thermally conductive plastics contain mineral fillers and achieve an isotropic thermal conductivity of up to 2 W/mK and electrical insulation at the same time. In order to obtain higher conductivities, use can be made of hexagonal boron nitride, for example. Here, too, the electrical insulation is provided and the thermal conductivity in a plane, for example in the X-/Y-direction, can be raised to 3 W/mK to 7 W/mK. However, in the Z-direction, i.e., perpendicular to the plane, the thermal conductivity is only 1 W/mK to 3 W/mK. Moreover, hexagonal boron nitride is very expensive.

Then, a combination of a carrier made of a graphite-filled plastic and a carrier made of a mineral-filled plastic can be used as a substrate. The graphite-filled plastic is thermally highly conductive with a thermal conductivity of up to 30 W/mK, but is electrically conductive. Although the mineral-filled plastic has a lower thermal conductivity, it is electrically insulating. By way of example, such a substrate can be produced in a 2-component injection molding method. Then, the wiring plane is formed and the corresponding optoelectronic component is arranged on the substrate. Nevertheless, the thermal conductivity of the substrate is restricted and the costs of these luminaires are high.

### SUMMARY

In various embodiments, a substrate for receiving an optoelectronic component is provided. The substrate includes a carrier body, and filler particles, which are embedded in the carrier body and which each have an electrically and thermally highly conductive core and an electrically insulating enveloping layer.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a lateral sectional view of an embodiment of a substrate;

FIG. 2 shows a lateral sectional view of an embodiment of an optoelectronic assembly;

FIG. 3 shows a flowchart of an embodiment of a method for producing a substrate; and

FIG. 4 shows a flowchart of an embodiment of a method for producing an optoelectronic assembly.

### DESCRIPTION

The following detailed description refers to the accompanying drawings that show, by way of illustration, specific details and embodiments in which the invention may be practiced.

In the following detailed description, reference is made to the accompanying drawings, which form part of this description and show for illustration purposes specific embodiments in which the invention can be implemented. Since component parts of embodiments can be positioned in a number of different orientations, the direction terminology serves for illustration and is not restrictive in any way whatsoever. It goes without saying that other embodiments can be used and structural or logical changes can be made, without departing from the scope of protection of the present invention. It goes without saying that the features of the various embodiments described herein can be combined with one another, unless specifically indicated otherwise. Therefore, the following detailed description should not be interpreted in a restrictive sense, and the scope of protection of the present invention is defined by the appended claims. In the figures, identical or similar elements are provided with identical reference signs, insofar as this is expedient.

Various embodiments provide a substrate for receiving an optoelectronic component, which is producible in a simple, fast and/or cost-effective manner and/or which contributes to the optoelectronic component being operable efficiently, at a higher power and/or over a long period of time.

Various embodiments provide an optoelectronic assembly, which is producible in a simple, fast and/or cost-effective manner and/or which is operable efficiently and/or over a long period of time and/or which requires particularly few optoelectronic components for producing light with a predetermined luminous intensity.

Various embodiments provide a method for producing a substrate, which can be implemented in a simple, fast and/or cost-effective manner and/or which contributes to an optoelectronic component arranged on the substrate being operable efficiently and/or over a long period of time.

Various embodiments provide a method for producing an optoelectronic assembly, which can be implemented in a simple, fast and/or cost-effective manner and/or which contributes to the optoelectronic assembly being operable efficiently and/or over a long period of time.

Various embodiments provide a substrate for receiving an optoelectronic component, including a carrier body, which has an electrically insulating embodiment, and filler particles, which are embedded in the carrier body and which each have an electrically and thermally highly conductive core and an electrically insulating enveloping layer.

The electrically and thermally highly conductive cores cause the thermal conductivity of the substrate to be particularly high. The isotropic thermal conductivity of the substrate obtainable thereby lies in a range, e.g., from 2 W/mK to 20 W/mK, e.g., from 5 W/mK to 15 W/mK, e.g., from 6 W/mK to 7 W/mK. The electrically and thermally highly conductive filler particles consequently significantly increase the thermal conductivity of the substrate in comparison with a substrate that only has the carrier body.

The electrically insulating enveloping layers bring about electrical insulation of the filler particles to the outside and of the substrate overall. Consequently, the filler particles are electrically insulated on the surface thereof, as a result of which the substrate overall is not electrically conductive.

As a result of the substrate being thermally highly conductive, heat arising during the operation of the optoelectronic component can be dissipated quickly and efficiently via the substrate. This contributes to the optoelectronic component being able to be operated in an operational range in which it is very efficient. Moreover, this can contribute to the optoelectronic component having a particularly long service life. Further, this renders it possible to be able to operate the optoelectronic component with a particularly high power, e.g. with a particularly high operating current. At the same time, the substrate can be produced in a cost-effective manner. In various embodiments, substantially lower costs arise in comparison with the materials that are conventionally necessary for achieving similarly high thermal conductivities.

Consequently, the substrate is producible in a simple, fast and/or cost-effective manner and contributes to the optoelectronic component being operable efficiently, at a higher power and/or over a long period of time.

According to a development, the cores include a metal or said cores are formed therefrom. By way of example, the filler particles can be formed by a metal powder. As an alternative or in addition thereto, the filler particles can be formed by other electrically conductive materials, such as graphite or carbon fibers, for example. This contributes to it being possible to produce the substrate in a particularly simple and/or cost-effective manner and/or to the substrate having a particularly high thermal conductivity. Further, the abrasivity when using such filler particles is significantly lower than in the case of the mineral or ceramic fillers, which are conventionally used for increasing the thermal conductivity in the case of electrical insulation. In the case where use is made of injection molding for forming the substrate, this has a direct effect on the service life of the extruder or the injection-molding machine and thus reduces costs and unwanted abrasion. The mechanical properties of the injection-molded product, such as the fracture strain, for instance, also can be influenced positively, for example by using electrically insulating carbon fibers as filler particles.

According to a development, the enveloping layer includes an oxide layer, a nitride layer or an oxynitride layer or said enveloping layer is formed therefrom. By way of example, if the filler particles are formed by a metal powder, the enveloping layer can be coated by a layer made of an oxide, a nitride or an oxynitride of the same metal. Alternatively, the electrically insulating enveloping layers can include SiO₂ or Al₂O₃ or said enveloping layers can be formed therefrom. Further, the cores can be coated with a suitable dispersing agent, the molecules and/or atoms of which accumulate on the surfaces of the cores on account of chemical bonds.

According to a development, the carrier body includes a plastic or said carrier body is formed therefrom. The plastic has an electrically insulating embodiment. This contributes in a simple manner to the substrate having an electrically insulating embodiment. By way of example, the plastic can be a thermosetting resin or a thermoplastic resin. By way of example, the plastic can include polyamide (PA), polybutylene terephthalate (PBT), polypropylene (PP), polyphenylene sulfide (PPS) and/or polyphthalamide (PPA) or said plastic can be formed therefrom. The plastic can be highly fillable without significantly changing its mechanical properties. By way of example, a degree of the fill of the filler particles can lie in a range from 30 to 90 wt %, without the plastic significantly changing its mechanical properties.

According to a development, the filler particles have an aspect ratio in a range from 1 to 1/10. By way of example, the particles have great symmetry and/or an elliptical or spherical embodiment. This can contribute to the thermal conductivity being particularly isotropic, for example more isotropic than in the case of hexagonal boron nitride, the best conventional electrically insulating filler with a high thermal conductivity. In this application, the aspect ratio denotes the ratio of height to width of one of the filler particles and/or the ratio of the maximum length of one of the filler particles to the maximum width of the same filler particle, with the maximum width being measured perpendicular to the maximum length.

According to a development, the filler particles are spherical. When using injection molding to form the carrier body, the viscosity of the melt of carrier material and spherical filler particles is particularly low in the corresponding injection-molding tool. This contributes to particularly fine structures of the injection-molding tool being able to be filled and to a particularly low injection pressure being able to be used. As a result of the latter, the plastic molecules experience no damage, or only negligibly small damage, during the injection-molding method. This contributes to the substrate being particularly stable.

According to a development, the electrically highly conductive cores each have an electric conductivity in a range from 1*10⁶ 1/Ωm to 61*10⁶ 1/Ωm, e.g. from 10*10⁶ 1/Ωm to 50*10⁶ 1/Ωm, e.g. from 20*10⁶ 1/Ωm to 40*10⁶ 1/Ωm, where 1/Ωm corresponds to 1S/m. This can contribute to the cores having a particularly high thermal conductivity.

According to a development, the thermally highly conductive cores each have a thermal conductivity in a range from 10 W/mK to 500 W/mK, e.g. from 100 W/mK to 400 W/mK, e.g. from 150 W/mK to 200 W/mK. This contributes to the substrate having a particularly high thermal conductivity.

According to a development, the filler particles have a maximum diameter in a range from 1 82 m to 100 82 m, e.g. from 10 82 m to 30 82 m. This contributes to being able to use many different shaping methods to produce the substrate from the melt of carrier material and filler particles.

According to a development, the enveloping layers have a thickness in a range from 1 nm to 1 82 m, e.g. from 2 nm to 10 nm, e.g. from 3 nm to 5 nm. This contributes to a particularly good electrical insulation by means of the enveloping layers.

Various embodiments provide the optoelectronic assembly, including the substrate explained above, at least one electrically conductive conductor track, which is embodied on the substrate, and at least one optoelectronic component, which is arranged on the substrate and which is electrically connected to the conductor track.

The effects and developments of the substrate explained above can be readily transferred to the advantages and developments of the optoelectronic assembly. Therefore, presenting these effects and developments again is foregone here and reference is made to the explanations made above.

On account of the substrate with the particularly high thermal conductivity, heat that is produced in the optoelectronic component during the operation of the optoelectronic assembly can be dissipated quickly and efficiently from the optoelectronic component via the substrate. This can contribute to the optoelectronic assembly being operable in an operational range in which it is very efficient and/or to the optoelectronic assembly having a particularly long service life. The fact that the optoelectronic component, and optionally further optoelectronic components, can be operated at a particularly high power, e.g. at a particularly high operating current, contributes to the optoelectronic assembly for producing light of a predetermined luminous intensity merely requiring fewer of the optoelectronic components in comparison with other optoelectronic assemblies in which the optoelectronic components only can be operated at a lower power.

On account of the electrically insulating substrate overall, the electrically conductive conductor track and, optionally, further electrically conductive conductor tracks can be formed directly on the substrate without an electrical short circuit being produced. This can contribute to the optoelectronic assembly being producible in a fast, simple and/or cost-effective manner.

If use is made of PBT or PP as a plastic, the one optoelectronic component and, optionally, one, two or more further optoelectronic components can be simply adhesively bonded to the carrier body, as a result of which the production costs of the corresponding optoelectronic assembly can be kept low. If use is made of PPS or PPA, the one optoelectronic component and, optionally, one, two or more further optoelectronic components can be soldered onto the carrier body, as a result of which a particularly good heat transfer from the optoelectronic components to the carrier body can be ensured.

Various embodiments provide a method for producing the substrate as explained above for receiving the optoelectronic component as explained above. In the method, electrically and thermally highly conductive filler particles are provided. The filler particles are treated in such a way that they each have an electrically and thermally highly conductive core and each have an electrically insulating enveloping layer, which surrounds the corresponding core. The filler particles are subsequently embedded in a carrier material. A dimensionally stable carrier body, in which the filler particles are embodied, is formed from the carrier material, wherein the carrier body and the filler particles form the substrate.

The effects and developments of the substrate explained above can be readily transferred to effects and developments of the method for producing the substrate. Therefore, presenting these effects and developments again is foregone here and reference is made to the explanations made above.

According to a development, the electrically insulating enveloping layers are formed by means of a predetermined oxidation process. A targeted oxidation occurs in the predetermined oxidation process. By way of example, an oxide formation at the surfaces of the metal particles of the metal powder, from which the cores are formed, is strengthened and/or accelerated in a suitable artificially produced atmosphere in comparison with an oxidation under normal conditions and/or laboratory conditions. This contributes to the enveloping layers being able to be produced in a simple, fast and/or cost-effective manner, since they can be produced directly from the metal powder itself.

The suitable, artificially produced atmosphere has an elevated temperature, an elevated oxygen concentration and/or an elevated air pressure, for example, in relation to the normal conditions and/or the laboratory conditions. By way of example, the normal conditions or the laboratory conditions are a room temperature of 20° C., a volume fraction of oxygen in the air of 20.942% and an air pressure of 1013 hPa.

As an alternative thereto, the enveloping layer can be produced by treating the particles in an oxygen plasma in the case of the oxidation layer as said enveloping layer, wherein an oxygen content, for example, can lie in a range from 20% to 100%, for example.

As an alternative or in addition thereto, the electrically insulating enveloping layer can be produced by means of electrochemical coating of the cores by means of a sol-gel process, in which the cores are coated with SiO₂, for example, by means of atomic layer deposition, in which the cores are coated with Al₂O₃, for example, or by means of chemical vapor deposition. Further, the cores can be coated with a suitable dispersing agent, the molecules and atoms of which accumulate at the surfaces of the cores by chemical bonds.

According to a development, an adhesion promoter and/or heat transfer promoter is added to the carrier material prior to the formation of the carrier body. The adhesion promoter contributes to a particularly good bond between the particles and the carrier body. The heat transfer promoter contributes to a particularly good heat transfer from the carrier body to the filler particles and from the filler particles to the carrier body.

Various embodiments provide a method for producing an optoelectronic assembly, wherein the substrate as explained above is produced, at least one electrically conductive conductor track is formed on the substrate, and at least one optoelectronic component is arranged on the substrate and electrically connected to the electrically conductive conductor track.

The effects and developments of the method for producing the substrate explained above can be readily transferred to effects and developments of the method for producing the optoelectronic assembly. Therefore, presenting these advantages and developments again is foregone here and reference is made to the explanations made above.

An optoelectronic assembly may include one, two or more optoelectronic components. Optionally, an optoelectronic assembly may also include one, two or more electronic components. An electronic component may include for example an active component and/or a passive component. An active electronic component may include for example a computing, control and/or regulating unit and/or a transistor. A passive electronic component may include for example a capacitor, a resistor, a diode or a coil.

An optoelectronic component can be an electromagnetic radiation emitting component or an electromagnetic radiation absorbing component. An electromagnetic radiation absorbing component can be for example a solar cell. In various embodiments, an electromagnetic radiation emitting component can be an electromagnetic radiation emitting semiconductor component and/or can be formed as an electromagnetic radiation emitting diode, as an organic electromagnetic radiation emitting diode, as an electromagnetic radiation emitting transistor or as an organic electromagnetic radiation emitting transistor. The radiation can be for example light in the visible range, UV light and/or infrared light. In this context, the electromagnetic radiation emitting component can be formed for example as a light emitting diode (LED), as an organic light emitting diode (OLED), as a light emitting transistor or as an organic light emitting transistor. In various embodiments, the light emitting component can be part of an integrated circuit. Furthermore, a plurality of light emitting components can be provided, for example in a manner accommodated in a common housing.

In this application, a body or material being thermally conductive means that the object or the material has a thermal conductivity in a range, e.g., from 2 W/mK to 20 W/mK, e.g., from 5 W/mK to 15 W/mK, e.g. from 6 W/mK to 7 W/mK.

In this application, a body or material being thermally highly conductive means that the object or the material has a thermal conductivity in a range, e.g., from 10 W/mK to 500 W/mK, e.g. from 100 W/mK to 400 W/mK, e.g. from 150 W/mK to 200 W/mK.

In this application, a body or material being electrically highly conductive means that the object or the material has an electrical conductivity in a range, e.g., from 1*10⁶ 1/Ωm to 61*10⁶ 1/Ωm, e.g. from 10*10⁶ 1/Ωm to 50*10⁶ 1/Ωm, e.g. from 20*10⁶ 1/Ωm to 40*10⁶1/Ωm.

In this application, a body or material being electrically insulating means that the object or the material has an electrical conductivity in a range, e.g., from 10⁻⁶ to 10⁻²⁴ 1/Ωm.

In various embodiments, a method for producing an optoelectronic assembly is provided. The method may include producing a substrate as described above or explained further below; forming at least one electrically conductive conductor track on the substrate; and arranging at least one optoelectronic component on the substrate and electrically connected to the electrically conductive conductor track.

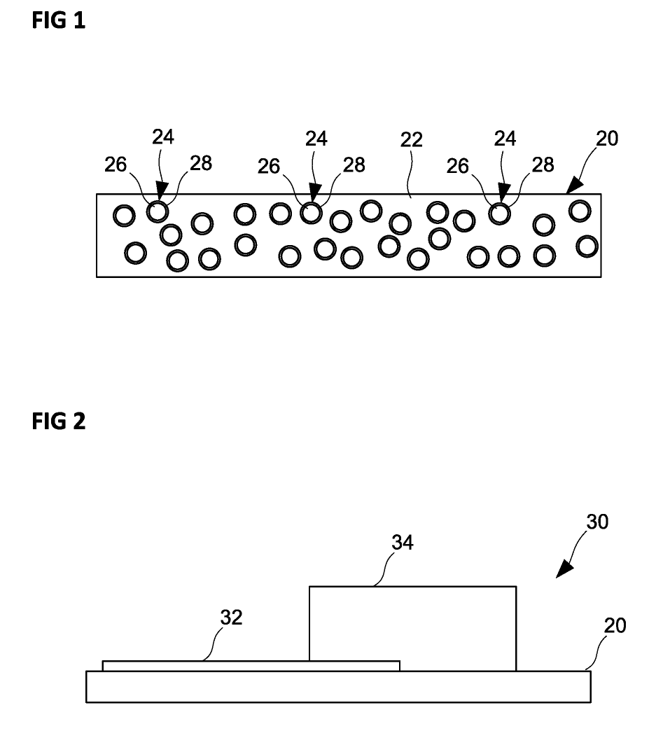

FIG. 1 shows a lateral sectional illustration of an embodiment of a substrate 20. The substrate 20 serves to receive an optoelectronic component (see FIG. 2). The substrate 20 can be part of a luminaire body of a luminaire.

The substrate 20 has a carrier body 22 and filler particles 24. The carrier body 22 has an electrically insulating embodiment. The carrier body 22 has an electrically insulating material or said carrier body is formed therefrom. The filler particles 24 are embedded in the carrier body 22. The filler particles 24 each have an electrically and thermally highly conductive core 26 and an electrically insulating enveloping layer 28.

Overall, the substrate 20 has a thermally conductive and electrically insulating embodiment. The substrate 20 has an isotropic thermal conductivity in a range from 2 W/mK to 20 W/mK, e.g., from 5 W/mK to 15 W/mK, e.g., from 6 W/mK to 7 W/mK. The electrically insulating enveloping layers 28 cause the filler particles 24 to be electrically insulating to the outside. The filler particles 24 that are electrically insulating to the outside and the electrically insulating carrier body 22 cause the substrate 20 overall to be electrically insulating. Overall, the substrate 20 can be electrically insulating in such a way that it has a breakdown voltage that lies in a range, e.g., from 500 V to 10 kV, e.g., from 500 V to 8 kV.

The cores 26 are formed from metal. By way of example, the cores 26 are formed from aluminum, silver, copper, iron, nickel or cobalt. Alternatively, the cores 26 can be formed by another electrically conductive material, such as graphite or carbon fiber, for example. By way of example, the filler particles 24 can be formed by electrically insulating carbon fibers. The electrically highly conductive cores 26 each have an electrical conductivity in a range, e.g., from 1*10⁶ 1/Ωm to 61*10⁶ 1/Ωm, e.g. from 10*10⁶ 1/Ωm to 50*10⁶ 1/Ωm, e.g. from 20*10⁶ 1/Ωm to 40*10⁶ 1/Ωm. The thermally highly conductive cores 26 each have a thermal conductivity in a range from 10 W/mK to 500 W/mK, e.g. from 100 W/mK to 400 W/mK, e.g. from 150 W/mK to 200 W/mK.

The enveloping layer 28 is an oxide layer. In various embodiments, the enveloping layer 28 includes or essentially consists of a metal oxide of the metal that forms the cores 26. By way of example, the enveloping layer 28 is formed from aluminum oxide, copper oxide, iron oxide, nickel oxide or cobalt oxide. As an alternative thereto, the enveloping layer 28 can be a nitride layer or an oxynitride layer. By way of example, the enveloping layer 28 then consists of a metal nitride or a metal oxynitride of the metal that forms the cores 26. As an alternative thereto, the electrically insulating enveloping layers 28 can include SiO₂ or Al₂O₃ or said enveloping layers can be formed therefrom. Further, the cores 26 can be coated with a suitable dispersing agent, the molecules and/or atoms of which accumulate on the surfaces of the cores 26 on account of chemical bonds. The enveloping layers 28 have an electrically insulating embodiment. The enveloping layers 28 can be electrically insulating in such a way that they each have a breakdown voltage that lies in a range, e.g., from 500 V to 10 kV, e.g. from 0.5 kV to 3 kV. The enveloping layers 28 each have a thickness in the range from 1 nm to 1 μm, e.g. from 2 nm to 10 nm, e.g. from 3 nm to 5 nm.

The carrier body 22 is formed from plastic. The plastic has an electrically insulating embodiment. By way of example, the plastic can be a thermosetting resin or a thermoplastic resin. By way of example, the plastic is polyamide (PA), polybutylene terephthalate (PBT), polypropylene (PP), polyphenylene sulfide (PPS) and/or polyphthalamide (PPA). Optionally, the plastic is highly fillable without losing its mechanical properties. By way of example, a degree of the fill of the filler particles 24 in the carrier body 22 can lie in a range from 30 to 90 wt %. The carrier body 22 can have a thermal conductivity in a range, e.g., from 0.15 W/mK to 0.2 W/mK. The carrier body 22 can have a volume resistivity in a range from 10¹² Ω/cm to 10¹⁵ Ω/cm, e.g., from 10¹³ Ω/cm to 10¹⁴ Ω/cm.

The filler particles 24 have a spherical embodiment. As an alternative thereto, the filler particles 24 can have an elliptical embodiment in cross section. By way of example, the filler particles 24 can have an aspect ratio in a range from 1 to 1/10, e.g. from 1 to 1/2.

In FIG. 1, the filler particles 24 are illustrated to be relatively large in relation to the thickness of the substrate 20 for improved visualization. In reality, the filler particles 24 can have a significantly smaller embodiment in relation to the thickness of the substrate 20. The filler particles 24 have a maximum diameter in a range from 1 μm to 100 μm, e.g. from 10 μm to 30 μm. The substrate 20 may have a thickness in a range, for example, from several 100 micrometer up to a few centimeters.

FIG. 2 shows a lateral sectional illustration of an embodiment of an optoelectronic assembly 30. The optoelectronic assembly 30 has a substrate 20, for example the above-described substrate 20. The optoelectronic assembly 30 can be part of a luminaire, wherein the substrate 20 can be part of a luminaire body of the luminaire.

At least one conductor track 32 is embodied on the substrate 20. In various embodiments, further conductor tracks, not illustrated in the figures, are embodied on the substrate 20. An optoelectronic component 34 is arranged on the substrate 20. In addition to the optoelectronic component 34, further optoelectronic components also can be arranged on the substrate 20. The optoelectronic component 34 is electrically connected to the conductor track 32 and optionally electrically connected to one or more of the further conductor tracks. The optoelectronic component 34 is partly arranged on the conductor track 32. As an alternative thereto, the optoelectronic component 34 can be arranged completely on the conductor track 32. As an alternative thereto, the optoelectronic component 34 can be arranged only next to the conductor track 32, wherein the optoelectronic component 34 then can be connected to the conductor track 32, for example by means of a wire. Should the carrier body 22 contain PBT or PP, or be formed therefrom, the optoelectronic component 34 can be securely adhered to the carrier body 22 by means of an adhesive. Should the carrier body 22 contain PPS or PPA, or be formed therefrom, the optoelectronic component 34 can be securely soldered to the carrier body 22.

The conductor track 32 serves to transport electrical current to the optoelectronic component 34 or away from the optoelectronic component 34. The substrate 20 serves as a carrier for the electrical conductor track 32 and the optoelectronic component 34 and for dissipating heat that arises in the optoelectronic component 34 during the operation of the optoelectronic component 34.

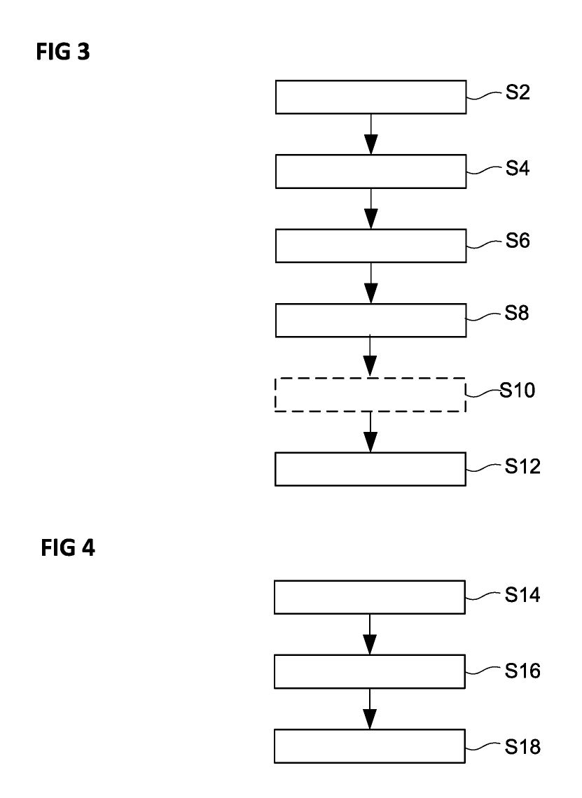

FIG. 3 shows a flowchart of an embodiment of a method for producing a substrate, for example the above-described substrate 20.

Particles, for example metal particles, for example in the form of a metal powder, are provided in S2. The particles can also be referred to as untreated filler particles. The particles include metal or said particles are formed therefrom. The particles are electrically and thermally highly conductive.

The particles are electrically insulated to the outside in S4. By way of example, the particles are subjected to a predetermined oxidation process. By way of example, the particles are arranged in a process chamber in which a suitable atmosphere is artificially produced. The suitable artificial atmosphere has an elevated temperature, an elevated pressure and/or an elevated oxygen content in relation to laboratory conditions and/or normal conditions. By way of example, the normal conditions or the laboratory conditions are a room temperature of 20° C., a volume fraction of the oxygen in the air of 20.942% and an air pressure of 1013 hPa. The particles are oxidized for a predetermined period of time under the suitable artificial atmosphere. Oxidizing the particles in the predetermined oxidation process causes an enveloping layer, for example the above-described enveloping layer 28, which arises in the process, to be particularly thick and/or to have particularly good electrically insulating properties. The oxidation process is stopped at a suitable time such that a non-oxidized core, for example the above-described core 26, remains under the enveloping layer 28. The core 26 and the enveloping layer 28 form the filler particles 24.

As an alternative or in addition thereto, the electrically insulating enveloping layer 28 can be produced by means of electrochemical coating of the cores 26, by means of a sol-gel process, in which the cores 26 are coated with SiO₂, for example, by means of atomic layer deposition, in which the cores 26 are coated with Al₂O₃, for example, or by means of chemical vapor deposition. Further, the cores 26 can be coated by means of a suitable dispersing agent, the molecules and atoms of which accumulate at the surfaces of the cores 26 by chemical bonds.

A carrier material for forming a carrier body, for example the above-described carrier body 22, is provided in S6. By way of example, the carrier material can include plastic or be a plastic. At this point, the carrier material may be available in a liquid or at least viscous state.

In S8, the filler particles 24 are added to the carrier material such that the filler particles 24 are embedded into the carrier material.

In an optional process S10, an adhesion promoter and/or heat transfer promoter can be added to the mixture of carrier material and filler particles 24. The adhesion promoter can be a heat transfer promoter at the same time. The adhesion promoter contributes to the carrier material adhering particularly well to the filler particles 24. The heat transfer promoter contributes to a particularly good heat transfer between the carrier material and the filler particles 24. By way of example, various silanes can be used as an adhesion promoter and/or heat transfer promoter, for example (3-glycidoxypropyl)trimethoxysilane.

Alternatively, the adhesion promoter or the heat transfer promoter can be admixed to the carrier material first and the filler particles 24 can then be added to this mixture. As an alternative thereto, the filler particles 24 can be admixed to the adhesion promoter and/or the heat transfer promoter and this mixture can then be mixed with the carrier material.

In S12, the mixture of carrier material and filler particles 24, and optionally of the adhesion promoter and/or the heat transfer promoter, is subjected to a shaping method, in which the mixture is made dimensionally stable. By way of example, the shaping method is an injection molding method, a molding pressure method, a casting method or a 3D printing method, in which the substrate is provided with its form.

FIG. 4 shows a flowchart of an embodiment of a method for producing an optoelectronic assembly, for example the above-described optoelectronic assembly 30.

A substrate is provided in S14, for example the above-described substrate 20. By way of example, the substrate 20 is produced by means of the above-described method.

At least one conductor track, for example the above-described conductor track 32, is formed on the substrate 20 in S16. By way of example, the conductor track 32 can be formed by a metallization of a surface of the substrate 20. By way of example, the metallization can be embodied by means of hot stamping of a structured metal film or by means of laser direct structuring (LDS). In addition to the conductor track 32, one or more further conductor tracks and/or circuit carriers can be formed on the substrate 20.

At least one optoelectronic component, for example the above-described optoelectronic component 34, is arranged on the substrate 20 and electrically connected to the conductor track 32 in S18. By way of example, the optoelectronic component 34 can be fastened to the substrate 20 by means of an adhesive or by means of soldering. Electrical contacting of the optoelectronic component 34 likewise can be brought about by means of an adhesive, e.g. an electrically conductive adhesive, or by means of soldering, for example. By way of example, the optoelectronic component 34, in one work process, can be fastened to the substrate 20 and electrically connected to the conductor track 32.

Various embodiments are not restricted to the specified embodiments. By way of example, the electrically and thermally highly conductive cores 26 may include a different material to the materials specified. By way of example, the electrically insulating enveloping layers 28 may include a different material to the materials specified. By way of example, a far more complex circuit than the circuit shown in FIG. 2 may be embodied on the substrate 20.

### LIST OF REFERENCE SIGNS

| | |
|---|---|
| Substrate | 20 |
| Carrier body | 22 |
| Filler particles | 24 |
| Core | 26 |
| Enveloping layer | 28 |
| Assembly | 30 |
| Conductor track | 32 |
| Component | 34 |
| Processes | S2 to S18 |

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A substrate for receiving an optoelectronic component, the substrate comprising:
a carrier body; and
filler particles, which are embedded in the carrier body and which each have an electrically and thermally highly conductive core and an electrically insulating enveloping layer.

2. The substrate of claim 1,
wherein the cores include a metal or said cores are formed therefrom.

3. The substrate of claim 1,
wherein the enveloping layer includes an oxide layer, a nitride layer or an oxynitride layer or said enveloping layer is formed therefrom.

4. The substrate of claim 1,
wherein the carrier body includes a plastic or said carrier body is formed therefrom.

5. The substrate of claim 1,
wherein the filler particles have an aspect ratio in a range from 1 to 1/10.

6. The substrate of claim 5,
wherein the filler particles are spherical.

7. The substrate of claim 1,
wherein the electrically highly conductive cores each have an electric conductivity in a range from 1*10⁶ 1/Ωm to 61*10⁶ 1/Ωm.

8. The substrate of claim 7,
wherein the electrically highly conductive cores each have an electric conductivity in a range from 10*10⁶ 1/Ωm to 50*10⁶ 1/Ωm.

9. The substrate of claim 8,
wherein the electrically highly conductive cores each have an electric conductivity in a range from 20*10⁶ 1/Ωm to 40*10⁶ 1/Ωm.

10. The substrate of claim 1,
wherein the thermally highly conductive cores each have a thermal conductivity in a range from 10 W/mK to 500 W/mK.

11. The substrate of claim 10,
wherein the thermally highly conductive cores each have a thermal conductivity in a range from 100 W/mK to 400 W/mK.

12. The substrate of claim 1,
wherein the filler particles have a maximum diameter in a range from 1 μm to 100 μnm.

13. The substrate of claim 12,
wherein the filler particles have a maximum diameter in a range from 10 μm to 30 μm.

14. The substrate of claim 1,
wherein the enveloping layers have a thickness in a range from 1 nm to 1 μm.

15. The substrate of claim 14,
wherein the enveloping layers have a thickness in a range from 2 nm to 10 nm.

16. An optoelectronic assembly, comprising:
a substrate, comprising:
a carrier body; and
filler particles, which are embedded in the carrier body and which each have an electrically and thermally highly conductive core and an electrically insulating enveloping layer.
at least one electrically conductive conductor track, which is embodied on the substrate; and
at least one optoelectronic component, which is arranged on the substrate and which is electrically connected to the conductor track.

17. A method for producing a substrate for receiving an optoelectronic component,
the method comprising:
providing electrically and thermally highly conductive filler particles;
treating the filler particles in such a way that they each have an electrically and thermally highly conductive core and each have an electrically insulating enveloping layer, which surrounds the corresponding core;
subsequently embedding the filler particles in a carrier material; and
forming a dimensionally stable carrier body, which forms the substrate, from the carrier material with the filler particles embedded therein.

18. The method of claim 17,
wherein the electrically insulating enveloping layers are formed by means of a predetermined oxidation process.

19. The method of claim 17,
wherein the electrically insulating enveloping layers are formed by means of a predetermined oxidation process.

20. The method of claim 17,
wherein at least one of an adhesion promoter or heat transfer promoter is added to the carrier material prior to the formation of the carrier body.
